(19) United States
(12) Patent Application Publication
(10) Pub. No.: US 2018/0205223 A1
(43) Pub. Date: Jul. 19, 2018

(54) Current Limiter Device Having A Coil And A Switch

(71) Applicant: Siemens Aktiengesellschaft, Muenchen (DE)

(72) Inventor: Christian Schacherer, Hallerndorf (DE)

(73) Assignee: Siemens Aktiengesellschaft, Muenchen (DE)

(21) Appl. No.: 15/743,845

(22) PCT Filed: Jun. 16, 2016
(86) PCT No.: PCT/EP2016/063900

§ 371 Date: Jan. 11, 2018

(30) Foreign Application Priority Data
Jul. 17, 2015 (DE) 10 2015 213 494.6

(51) Int. Cl. H02H 9/02; H01L 39/18

(52) U.S. Cl. CPC H02H 9/023; H01L 39/126; H01L 39/18

(57) ABSTRACT

The present disclosure relates to current limiter devices. Various embodiments thereof may be useful for limiting a short-circuit current in a superordinate electrical supply system, wherein the current limiter device has a current-limiting coil device and a switch electrically connected in series with the coil device and/or methods for limiting a short-circuit current in an electrical supply system with such a current limiter device. For example, some current limiter devices for limiting a short-circuit current in a superordinate electrical supply system may include: a current-limiting coil device; and a switch connected in series with the coil device. The switch may comprise a load interrupter switch.

### CROSS-REFERENCE TO RELATED APPLICATIONS

This application is a U.S. National Stage Application of International Application No. PCT/EP2016/063900 filed Jun. 16, 2016, which designates the United States of America, and claims priority to DE Application No. 10 2015 213 494.6 filed Jul. 17, 2015, the contents of which are hereby incorporated by reference in their entirety.

### TECHNICAL FIELD

The present disclosure relates to current limiter devices. Various embodiments thereof may be useful for limiting a short-circuit current in a superordinate electrical supply system, wherein the current limiter device has a current-limiting coil device and a switch electrically connected in series with the coil device and/or methods for limiting a short-circuit current in an electrical supply system with such a current limiter device.

### BACKGROUND

Known current limiter devices usually have a current-limiting coil device that exhibits a rapid and abrupt rise in its impedance in the event of a short circuit. In particular examples, such a coil device may be a superconductive coil device in which the superconductive properties break down if a critical current density is exceeded. As a result, the impedance and the temperature of the coil device rise very quickly and automatically without a switching process initiated by an external control unit. In addition, this sudden increase in the impedance is reversible, which means that after the cause of the short circuit has been removed it is possible for operation in the superconductive state to be resumed usually very quickly. In many cases, it is necessary to wait only a very short time until the superconductive conductor has been cooled to an operating temperature below its transition temperature again after the short circuit event.

The current-limiting coil device may include a resistive coil device, for example, in the case of which the resistance of the coil rises very quickly as a result of breakdown of the superconductive properties. Alternatively, the coil device may include an inductively or inductively/resistively current-limiting coil device, in the case of which a considerable change in the inductance of the coil device is caused in the event of a short circuit. Said coil device include a normally conductive or superconductive inductor, for example.

Additionally, a superconductive secondary winding, which is not part of the circuit to be protected, can be used as a compensating coil that shields a magnetic field of the inductor and therefore lowers the inductance of the inductor during normal operation. In the event of a short circuit, the superconductive properties of the compensating coil also break down, in this case as a result of exceeding the critical current density of the inductive currents. This sudden change in the shielding effect of the compensating coil in turn changes the inductance of the inductor quickly and automatically, so the short-circuit current in the circuit to be protected can be limited quickly and reversibly in this case too. As an alternative to such a current limiter with a superconductive coil, other options for changing the inductance may be used. A further example may include a ground-fault neutralizer. In the case of such ground-fault neutralizers, a displaceable ferrous core, known as a plunger core, can be introduced into or removed again from the coil center of the inductor. In this way, it is possible to vary the inductance of the inductor.

A common feature of all of these variants of known current limiter devices is that a coil device interposed in the circuit can be used to effectively limit a short-circuit current. This usually automatic limiting is the first step to protect the electrical supply system. In a second step, the remaining current is then also shut down by the coil device, typically by opening a circuit breaker connected in series with the coil device, specifically typically at least until the cause of the short circuit is removed. In current limiter devices with superconductive coils, such a switch connected in series allows the time in which current flows through a superconductor that has become normally conductive to be limited to a very short period and, as a result, damage to the superconductive material, for example as a result of thermal overload, may be effectively prevented. This two-stage limiting and switching system allows the entire current limiter device to be available for conducting the full current again comparatively quickly after a fault is corrected. At the same time, the windings of the current-limiting coil device can be embodied in more material-saving fashion than would be necessary to protect against thermal overload without the additional switch.

According to the prior art, the additional switch comprises a circuit breaker so that, if necessary, a short-circuit current for a short circuit in the line section between switch and coil device can also be interrupted by virtue of the switch being operated. Such a short circuit in the region between switch and current-limiting coil device can no longer be limited by the coil device in advance in unfavorable configurations of the electrical supply system, but rather needs to be prevented solely or at least primarily by the operation of the switch. Therefore, the switch connected in series is designed as a circuit breaker that can reliably interrupt the full short-circuit current at the rated voltage of the electrical supply system.

A disadvantage of such current limiting devices is that where the serial switch comprises a circuit breaker a comparatively long interrupted time, inter alia, is also accepted besides the higher costs and an increased space requirement, among other things. Where there is a longer interrupted time for said switch, however, the remaining flow of current by the current limited in the first step through the coil device in the event of a short circuit lasts longer. The coil device must be correspondingly robust to withstand this limited current at least until the residual current is reliably interrupted by the circuit breaker. Particularly in the case of current-limiting coil devices with superconductive coil windings, this results in a high level of stress on the superconductive material and in larger required quantities of superconductive conductor material than would be the case with a faster switch.

### SUMMARY

The teachings of the present disclosure may enable a current limiter device that overcomes the cited disadvantages. In some embodiments, a current limiter device may be able to interrupt a residual current already limited by the coil device as quickly as possible. Some embodiments may include a method for limiting a short-circuit current with such a current limiter device.

For example, a current limiter device (3) for limiting a short-circuit current in a superordinate electrical supply system (1), may have a current-limiting coil device (5) and a switch (7) electrically connected in series with the coil device (5), wherein the switch (7) is configured as a load interrupter switch.

In some embodiments, the load interrupter switch (7) is electrically connected to that connection side (9b) of the coil device that, of the two connection sides (9a, 9b) in the superordinate electrical supply system (1), has the higher-impedance connection to a current source (11) of the electrical supply system (1) in the event of limiting.

In some embodiments, the load interrupter switch (7) is arranged adjacently to the coil device (5).

In some embodiments, there is no circuit breaker connected in series with the coil device (5).

In some embodiments, the load interrupter switch (7) has a switching capacity that corresponds to at least a current limited by the coil device (5) and is lower than the unlimited short-circuit current.

In some embodiments, load interrupter switch (7) has a switching capacity that corresponds to no more than five times a prescribed rated current of the superordinate electrical supply system (1).

In some embodiments, the load interrupter switch (7) has a switching capacity of no more than 10 kA at a rated voltage of 66 kV or less.

In some embodiments, the load interrupter switch (7) has an opening time of no more than 30 ms.

In some embodiments, the current-limiting coil device (5) has at least one coil with a superconductive conductor material.

In some embodiments, there is a cryostat (15), wherein both at least part of the current-limiting coil device (5) and at least one connection of the load interrupter switch (7) are arranged inside the cryostat.

In some embodiments, there are at least two current-limiting coil devices (5a, 5b), wherein the load interrupter switch (7) is arranged between the two coil devices (5a, 5b).

In some embodiments, there is a normally conductive parallel impedance (17) that is electrically connected in parallel with the current-limiting coil device (5) and with the load interrupter switch (7).

In some embodiments, the current-limiting coil device (5) is a resistively current-limiting coil device.

In some embodiments, the current-limiting coil device (5) is an inductively/resistively current-limiting coil device.

Some embodiments may include a method for limiting a short-circuit current in an electrical supply system (1) with a current limiter device (3) as claimed in one of claims 1 to 14, in which in the event of a short circuit: a short-circuit current flowing through the coil device (5) is limited to a prescribed limit current by means of the coil device (5), and the limit current flowing through the load interrupter switch (7) is interrupted by virtue of the load interrupter switch (7) being opened.

### BRIEF DESCRIPTION OF THE DRAWINGS

The disclosure continues below with reference to various embodiments depicted in the appended drawings, in which:

FIG. 1 shows a schematic equivalent circuit diagram of a current limiter device according to teachings of the present disclosure;

FIG. 2 shows a schematic equivalent circuit diagram of a current limiter device according to teachings of the present disclosure;

FIG. 3 shows a schematic equivalent circuit diagram of a first superordinate electrical supply system with two exemplary short-circuit locations, according to teachings of the present disclosure;

FIG. 4 shows a schematic equivalent circuit diagram of a first superordinate electrical supply system with a third exemplary short-circuit location, according to teachings of the present disclosure;

FIG. 5 shows a schematic equivalent circuit diagram of a second superordinate electrical supply system with an exemplary short-circuit location, according to teachings of the present disclosure;

FIG. 6 shows a schematic equivalent circuit diagram of a third superordinate electrical supply system with an exemplary short-circuit location, according to teachings of the present disclosure; and

FIG. 7 shows a schematic equivalent circuit diagram of the third superordinate electrical supply system with an alternative short-circuit location according to teachings of the present disclosure.

### DETAILED DESCRIPTION

The current limiter devices described herein may be used to limit a short-circuit current in a superordinate electrical supply system. They may include a current-limiting coil device and a load interrupter switch electrically connected in series with the coil device. The switch may comprise a load interrupter switch.

In connection with the present disclosure, a short-circuit current means a current within the context of all established types of short circuits, that is to say not only a direct double-phase short circuit between two conductors of a system, but particularly also a single-phase short circuit (ground fault) between one conductor and ground, a three-phase short circuit between three conductors of a system, a two-phase- or three-phase-to-ground short circuit, and a double-line-to-ground fault. The terms “short circuit”, “short-circuit current” or “short-circuit event” therefore include the applicable terms of the other types of fault. In the present disclosure, the term “superordinate electrical supply system” means an electrical supply system in which a current limiter device as described herein is used as an electrical component. It is thus not “superordinate” in relation to the voltage level of the electrical supply system.

In the current limiter devices described herein, the current-limiting coil device may be used to limit a short-circuit current flowing via this coil device in a first step. The load interrupter switch connected in series therewith may be used to shut down the short-circuit current limited in this way in a second step. A load interrupter switch means a switch whose interrupting capacity is a low multiple of its prescribed rated current, but whose interrupting capacity is not dimensioned for interrupting a typical short-circuit current for a direct double-phase short circuit between two conductors of the superordinate electrical supply system.

A current limiter device as described herein, when connected in series, can be switched more quickly as a result of its embodiment as a load interrupter switch than a corresponding switch embodied as a circuit breaker. The correspondingly faster opening time means that the period for the flow of a short-circuit current, limited in a first step, through the current-limiting coil unit can be advantageously reduced. As a result, the current-limiting coil unit itself can be dimensioned for shorter operating times under the stress of the limited short-circuit current. In particular examples, the coil device may comprise smaller amounts of conductor material than would be possible if the current limiter device included a circuit breaker. The coil device can therefore be designed less expensively, smaller and/or lighter. The load switch itself can also be made less expensively than a corresponding circuit breaker.

Various methods described herein for limiting a short-circuit current in an electrical supply system may employ a current limiter device as described. In the event of a short circuit, a short-circuit current flowing through the coil device may be limited to a prescribed limit current by means of the coil device, and the limit current flowing through the load interrupter switch is interrupted by virtue of the load interrupter switch being opened. Advantageous refinements and developments are explored in the description that follows. In this case, the refinements of the current limiter device and of the method that are described can be combined with one another.

As such, the load interrupter switch may be electrically connected to that connection side of the coil device that, of the two connection sides of the coil device in the superordinate electrical supply system, has the higher-impedance connection to a current source of the electrical supply system in the event of limiting. In order words, the orientation of the switch relative to a current source of the electrical supply system is not arbitrary, but rather the switch may be arranged on a side of the coil device that is remote from the current source of the superordinate electrical supply system and that has the higher impedance to current source.

By way of example, in a relatively simple electrical supply system, one connection side of the coil device may be facing the current source (or multiple current sources on the same side of the coil device), and the other connection side of the coil device may be facing one or more loads of the electrical supply system. In the cited embodiment, the load interrupter switch is then arranged on the load side of the coil device. On the load side too, the electrical supply system is connected to the current source again as the line progresses, to form a closed circuit. On this load side, however, the connection of the coil device has a higher impedance than on the current source side, at least during current limiting, since the at least one load on this side is arranged between coil device and current source. In a simple electrical supply system with a current source side and a load side, the switch is thus, in other words, arranged on the load side of the coil device.

An arrangement of the switch on the load side of the coil device, in the event of a short circuit to a line section between switch and coil device, provides that only the coil device and not the switch carries the short-circuit current. The short-circuit current flowing through the coil device is therefore automatically limited to a prescribed limit current by the coil device. The switch can be optionally opened, but without the short-circuit current being interrupted in this case. The switch thus does not need to be embodied as a circuit breaker for this case.

Even in the case of more complex electrical supply systems having multiple current sources and/or multiple loads on the two connection sides of the coil device, the switch may be connected to the coil device on the connection side connected to the at least one current source at higher impedance. In this case too, this side connected to higher impedance is referred to as the load side. In this case, in the event of a short circuit to a line section between switch and coil device, a smaller current flows on the load side than on the opposite current source side. The risk that a current not limited by the coil device is so high than it can no longer be switched by the switch is lower when the switch is arranged on the load side. Further suitable current sources in a more complex electrical supply system of this kind are combined heat and power installations, photovoltaic installations and/or wind power installations, for example.

The load interrupter switch may be arranged adjacently to the coil device. In other words, the interspace between load interrupter switch and coil device may be free of electrical components, other than a connecting electrical conductor. A directly adjacent arrangement of this kind has the advantage that a short circuit to a line section between switch and coil device is much more unlikely than when there are also electrical components in this interspace. The shorter the distance between switch and coil device, the more unlikely in general is a short circuit in the region in between.

The current limiter device may be free of a circuit breaker connected in series with the coil device. In other words, the load interrupter switch is then used not in addition to a conventional circuit breaker but rather instead of such a circuit breaker. As a result, costs can be saved for the switch itself, since load interrupter switches can usually be embodied less expensively than circuit breakers. In particular examples, the current limiter device can be embodied so as to be free of any circuit breakers.

In some embodiments, however, a further circuit breaker may be arranged in series with the coil device in addition to the load interrupter switch. This may be beneficial particularly in the cases in which fast switching by the load interrupter switch is desirable to interrupt the flow of the limit current through the coil device quickly, cases in which, on the other hand, it is not possible to completely rule out a short circuit that results in an unlimited flow of current through the load interrupter switch on the load interrupter switch side. Such a short-circuit current may be so high that it cannot be interrupted by the load interrupter switch alone. In such cases, an additional circuit breaker arranged on the same side as the load interrupter switch, as seen from the coil device, can ensure that a short circuit of this kind between coil device and one of the two switches can also be reliably interrupted.

The load interrupter switch may have a switching capacity that corresponds to at least a current limited by the coil device and is lower than the unlimited short-circuit current. In other words, the load interrupter switch may be dimensioned such that it can effectively interrupt a limit current flowing through the coil device, but that it could not interrupt the unlimited short-circuit current that would flow in the electrical supply system without the action of the coil device, for example. The cited switching capacity may generally be the interrupting capacity of the load interrupter switch.

The superordinate circuit may generally be denoted by a prescribed rated current. The load interrupter switch can then have a switching capacity that corresponds to no more than five times a prescribed rated current of the superordinate electrical supply system. In particular examples, the switching capacity may be no more than three times this prescribed rated current. Such a switch cannot shut down an unlimited short-circuit current as an example of a short circuit between two conductors, but it can instead interrupt a current limited by the coil device with a much shorter switching time than a circuit breaker dimensioned for much higher switchable currents.

The load interrupter switch can have a switching capacity of no more than 10 kA at a rated voltage of 66 kV or less. A load interrupter switch of such dimensions can advantageously be used in medium-voltage systems for shutting down a current already limited by the coil device, without its switching capacity being adequate for shutting down an unlimited short-circuit current for a direct short circuit between two conductors.

The load interrupter switch may have an opening time of less than 70 ms, particularly no more than 30 ms. When such a fast switch is used, the coil device may comprise much less conductor material than for a slower switching time.

The current-limiting coil device may include at least one coil with a superconductive conductor material. Such a coil device is particularly suitable for causing breakdown of the superconductive properties and, as a consequence thereof, a fast and reversible rise in the resistance and/or in the inductance of the coil device when a threshold value for the current flowing in the electrical supply system is exceeded. In this case, the superconductor may be arranged as part of the superordinate electrical supply system, for example in a coil connected in series with the load interrupter switch. In these cases, the nonreactive resistance of this coil connected in series can be kept extremely low. Alternatively or additionally, the superconductor may also be arranged in a compensating coil inductively coupled to the superordinate electrical supply system.

The superconductive conductor material may have a high-temperature superconductor. High-temperature superconductors (HTS) are superconductive materials with a transition temperature above 25 K and, in the case of some material classes, for example Cuprate superconductors, above 77 K, in which the operating temperature can be reached by cooling with cryogenic materials other than liquid helium. The high-temperature superconductor can have, for example, magnesium diboride or an oxide ceramic superconductor, for example a compound of the type REBa₂Cu₃Oₓ (REBCO for short), where RE is an element from the rare earths or a mixture of such elements.

The current limiter device may include a cryostat, wherein both at least part of the current-limiting coil device and at least one isolating distance of the load interrupter switch are arranged inside the cryostat. Such an arrangement is particularly advantageous if the current-limiting coil device has a coil with a superconductive conductor material. This coil can then be cooled to an operating temperature below the transition temperature of the superconductor by the cryostat. Arranging the isolating distance of the load interrupter switch in the same cryostat is particularly advantageous because the probability of a short circuit striking in the region between coil device and load interrupter switch can then be reduced to the greatest possible extent. The switch then also no longer necessarily needs to be dimensioned such that it could interrupt an as yet unlimited short-circuit current. A mechanical drive that may be present for the load interrupter switch may likewise be arranged in the cryostat, this not necessarily needing to be the case. To achieve the advantages when avoiding adverse short circuits, it suffices for the isolating distance of the switch to be arranged in the cryostat and for the drive to be outside.

The current limiter device may comprise at least two current-limiting coil devices, wherein the load interrupter switch is arranged between the two coil devices. The two current-limiting coil devices may particularly be connected among one another and electrically in series with the switch. In such a butterfly-like configuration, the load side, that side with the higher impedance to a current source of the electrical supply system in the event of limiting, for each of the two coil devices is the side facing the respective other coil device. Therefore, the switch arranged between the two coil devices is arranged on the load side for the two coil devices.

The effect of this is that both in the case of simple electrical supply systems with only one or a few adjacent current source(s) and in the case of more complex electrical supply systems with multiple distributed current sources, the load interrupter switch never needs to interrupt the full unlimited short-circuit current in the event of short circuits impacting at arbitrary locations. Instead, irrespective of the side for the current source and irrespective of the side for the impacting short circuit, the current flowing through the load interrupter switch is limited at least by one of the current-limiting coils to the limit current thereof after a very short response time by said coils. Such a butterfly configuration can thus achieve the effect that even a load interrupter switch that cannot switch the unlimited current can be used to reliably isolate any type of short circuit occurring for any type of arrangement of the current source the electrical supply after the occurrence of a short circuit. Although two current-limiting coils are needed, each individual one of the two coils can be constructed with much less conductor material, particularly also can be constructed with much less than half of the conductor material than would be needed for a current limiter device with only one coil device in series with a circuit breaker. This is again due to the much shorter switching time of the load interrupter switch, so that conductor material, in particular superconductive conductor material, can be saved overall.

In some embodiments, the load interrupter switch with the exception of the conductive connection is arranged as a single electrical component between the two current-limiting coil devices.

The advantages of the butterfly configuration described take particular effect if each of the two current-limiting coil devices has a superconductive conductor material and at least the superconductive parts of the two coil devices are arranged together with the load interrupter switch in a superordinate cryostat.

The current limiter device may include a normally conductive parallel impedance that is electrically connected in parallel with the current-limiting coil device and with the load interrupter switch. A parallel impedance of this kind may be used to keep down electrical losses in the current-limiting coil device in the event of limiting. Particularly in the case of a superconductive, resistively current-limiting coil device, the resistance of the coil device may be relatively high after a breakdown of the superconductive properties. To avoid excessive heating of the superconductive conductor material, it may be expedient to provide a parallel current path that can carry part of the residual current in the event of a short circuit. During normal operation, on the other hand, this parallel path barely contributes to current transport, since the parallel impedance is generally configured to be much higher than the impedance of the current-limiting coil device. In the event of a short circuit, a residual current limited by the impedance of the switch can then flow via the parallel impedance even after the switch is opened, without the superconductive coil device still being stressed in this case.

The current-limiting coil device may be a resistively current-limiting coil device. It may particularly be denoted by the features described for this current limiter type in the introduction in connection with the prior art. Alternatively, the current-limiting coil device may be an inductively or inductively/resistively current-limiting coil device. This may also be denoted by the features described for this current limiter type in the introduction in connection with the prior art.

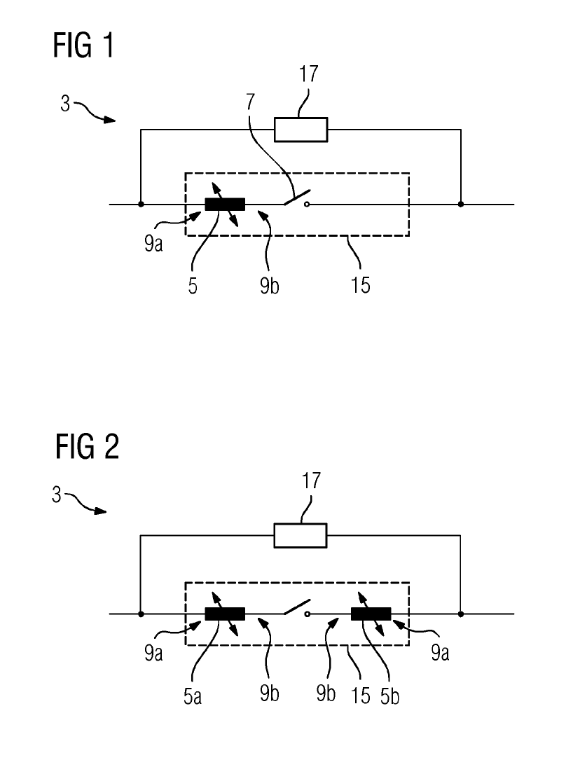

FIG. 1 shows a schematic equivalent circuit diagram with a current limiter device 3 according to a first exemplary embodiment of the teachings herein. The current limiter device has a current-limiting coil device 5 that is electrically connected in series with a switch 7. These two components are electrically connected in parallel with an additional parallel impendence 17. The current-limiting coil device 5 may include a superconductive resistive current limiter coil, for example, or it can have an inductor whose inductance can rise abruptly in the event of a short circuit. The inductor may also either itself comprise a superconductive conductor material, and/or it may be provided with an additional compensating coil whose conductor material is superconductive. In all of these cases, in which at least part of the current-limiting coil device has a superconductive conducting material, the arrangement of at least the superconductive part in a cryostat is expedient.

Therefore, in the example shown, the whole superconductive current-limiting coil device is arranged in the cryostat 15, which in this case also surrounds the switch 7 connected in series. The switch may optionally also be arranged outside the cryostat 15, however, since it has no superconductor. An arrangement in the cryostat 15, as shown here, is advantageous, however, to decrease the risk of a short circuit impacting in the region between coil device and switch. The switch 7 is configured as a load interrupter switch with an opening time below 30 ms and an interrupting capacity below 10 kA. The load interrupter switch 7 is arranged on what is known as the load side 9b of the coil device 5 and remotely from what is known as the current source side 9a, the load side having a higher-impedance connection to a current source of the circuit in a superordinate circuit than the current source side.

FIG. 2 shows a schematic example of a current limiter device according to a second exemplary embodiment of the present disclosure. This current limiter device is of similar design to that of the first exemplary embodiment, but it has not only a first 5a but also a second current-limiting coil device 5b, the load interrupter switch 7 being electrically connected in series between these two coil devices 5a and 5b. These three components 5a, 5b and 7 are in turn arranged together inside a cryostat 15 that can be used to cool superconductive conductor elements of the current-limiting coil devices. In regard to a superordinate circuit, the outer sides of the coil devices 5a and 5b are each the current source sides 9a and the inner sides are the load sides 9b, since in the event of limiting the two coil devices 9a and 9b act as high resistances, for example when the superconductive properties break down as a result of a prescribed current threshold being exceeded. The load sides of the two coil devices 5a and 5b are then on the inside even if this current limiter device 3 of butterfly-like design is arranged in a more complex electrical supply system with multiple current sources and multiple loads, as will be shown below.

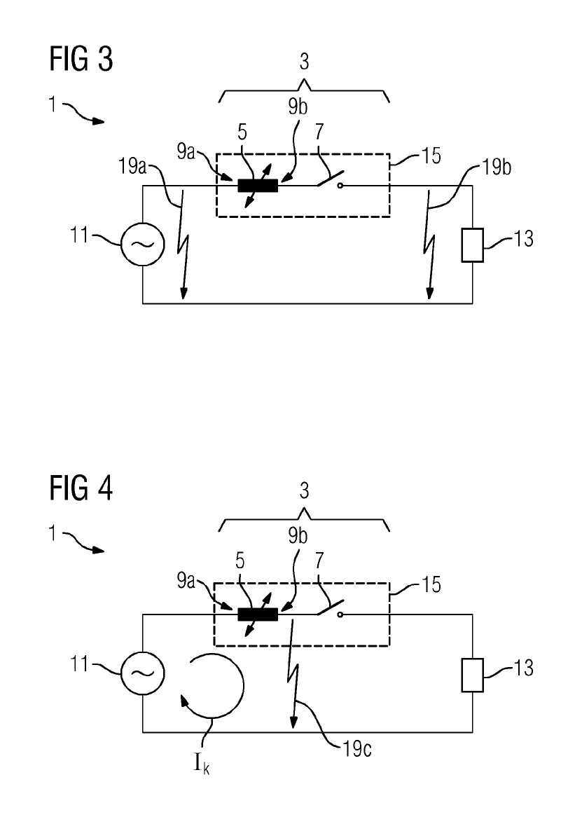

FIG. 3 shows a schematic single-phase equivalent circuit diagram of a first superordinate electrical supply system 1, depicted in simplified fashion, with a current limiter device 3 according to the present disclosure, a current source 11, and a load 13. In this arrangement, the current source 11 and the load 13 may each also represent multiple current sources and loads. The current limiter device 3 in turn comprises a current-limiting coil device 5 and a load interrupter switch 7, which are arranged together in a cryostat 15. It thus substantially corresponds to the current limiter device 3 from the example of FIG. 1, but without the optional parallel impedance, which is not shown here just for the sake of clarity. As in FIG. 1, the load interrupter switch 7 is arranged on the load side 9b of the coil device 5. As a result of the interposition of the load 13, this side has a higher impedance to the current source 11 than the other side 9a, the current source side, even without the switch 7.

The response of the system to different possible short circuits shall now be outlined. A first possible short-circuit position 19a corresponds in this case to a short circuit that connects the two conductors to one another in proximity to the current source 11. In the electrical supply system 1 shown, such a short circuit results in a high short-circuit current that is not limited by the apparatuses shown. The electrical supply system 1 is thus not protected against such short circuits on the current source side.

A second possible short-circuit position 19b corresponds to a short circuit between the two conductors on the load side. The electrical supply system is protected against short circuits of this kind by the interposed current limiter device. In the event of a short circuit of type 19b, the load 13 is bypassed, and a very much higher short-circuit current initially flows through the current-limiting coil device 5, said short-circuit current being very quickly limited to a prescribed limit current, however, for example by a breakdown of the superconductive properties of a conductor part in the coil device 5. Subsequently, when such a short-circuit event is detected, opening of the load interrupter switch 7 is triggered, which means that the time of the limit current flowing through the coil device is kept very short.

The use of a load interrupter switch 7 with an opening time of less than 30 ms, for example, allows this time to be kept very much shorter than when a circuit breaker dimensioned for higher interrupting currents is used for interrupting. As a result, the current-limiting coil device 5 can be dimensioned to be smaller, since heating by the limit current flowing in the coil device 5 is effectively minimized over the short period. Since the short-circuit current in the event of a short circuit of type 19b is already limited by the coil device 5 before it is interrupted by the load interrupter switch 7, this switch also does not need to be designed for interrupting the full short-circuit current. This consideration applies generally for a short circuit of type 19b, irrespective of whether the load interrupter switch 7 is on the current source side 9a or the load side 9b of the coil device 5.

FIG. 4 again shows the same schematic equivalent circuit diagram of the first superordinate electrical supply system 1, analogously to in FIG. 4. In this case, however, a third exemplary short-circuit type is shown, in which connection of two conductors takes place at the short-circuit position 19c, so that a short circuit to a region between the coil device 5 and the load interrupter switch 7 of the current limiter device 3 is triggered. As a result, an annularly closed short-circuit current thus flows along the schematically shown short-circuit current path Iₖ. This annular short-circuit current is limited to a prescribed limit current by the coil device 5 similar to the case of a short circuit 19b of FIG. 3. Subsequent opening of the load interrupter switch 7 is then not necessary, since the current Iₖdoes not flow via the load interrupter switch 7 at all on account of the position of the short circuit. Opening of the load interrupter switch 7 is optional in such a case. What is important is that even in the event of a short circuit of this kind between the components of the current limiter device, the load interrupter switch does not have to interrupt a current above the prescribed limit current. This is achieved by virtue of its arrangement on the load side 9b of the coil device 5.

In the event of a short circuit at the position 19c, it may be advantageous to arrange one or more additional load interrupter switches between the current source 11 and the coil device 5, since a further load interrupter switch of this kind can then likewise be used to reliably interrupt an already limited current flowing through the coil device 5 in the event of a short circuit 19c, and the coil device 5 can therefore be protected against overheating. In this configuration, the short-circuit current limited by the coil device 5 can always be interrupted by a load interrupter switch. Then different switches may be opened depending on the short circuit event.

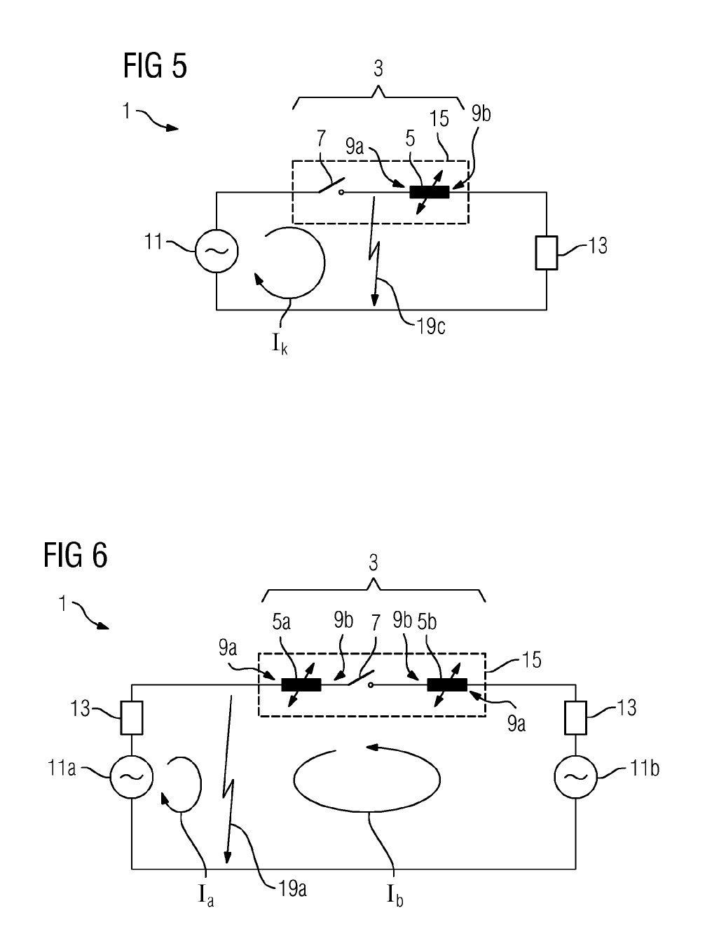

To depict this effect of the load-side arrangement more accurately, FIG. 5 shows an alternative arrangement of the load interrupter switch 7 on the current source side 9a of the coil device 5. A short circuit at the applicable position 19c is shown, that is to say in a region between load interrupter switch 7 and coil device 5. Such a short circuit of type 19c again results in an annularly closed short-circuit current Iₖ, which now flows only via the switch 7 and not via the coil device 5, however. In such an arrangement, said short-circuit current is thus not effectively limited by the coil device 5, but rather could at most be interrupted by virtue of the switch 7 being opened. Since this switch 7 is designed as a load interrupter switch and not as a circuit breaker in this case, however, and also no further circuit breaker is otherwise connected in series, the switch 7 cannot interrupt this current. The example shown in FIG. 5, for the reasons cited, may be expedient only when a short circuit of type 19c has a very low probability of occurring. There is a considerable reduction in this probability, for example, as a result of the load interrupter switch 7 and the coil device 5, as shown in FIGS. 1 to 5, being arranged together in a cryostat.

FIG. 6 shows a schematic equivalent circuit diagram of a third superordinate electrical supply system 1 with an alternative current limiter device 3. The current limiter device 3 comprises two current-limiting coil devices 5a and 5b and an interposed load interrupter switch 7, which are arranged together in a cryostat 15. It thus substantially corresponds to the current limiter device 3 from the example of FIG. 2, but again without the optional parallel impedance, which is not shown here for the sake of clarity. The third superordinate electrical supply system 1 is a more complex electrical supply system with at least two current sources 11a and 11b and also multiple loads 13. For the whole current limiter device 3, a load side and a current source side thus cannot be associated as explicitly as in the simpler electrical supply systems of FIGS. 3 to 5. For each of the two current-limiting coil devices 5a and 5b, however, the side faced by the other coil device 5b or 5a can be regarded as the load side 9b and the side remote therefrom can be regarded as the current source side 9a, since at least in the event of limiting, after the impedance of the respective coil device 5b or 5a is increased, this is the higher-impedance side.

FIG. 6 likewise schematically shows a first short-circuit current path Iₐ, flowing at the position 19a in the event of a short circuit, that arises for the current supplied from the first current source 11a. The second short-circuit current path for the current supplied from the second current source 11b is denoted by I_{b}, on the other hand. As can be seen in FIG. 6, the electrical supply system is, similarly to in the case of the example in FIG. 3, not protected against the current flowing on the first short-circuit current path 19a, since the current limiter device 3 is not situated on this path. For the short-circuit current path I_{b} supplied from the second current source 11b, however, the current limiter device 3 exhibits its full effect and initially limits the short-circuit current to the prescribed limit current by virtue of the effect of the two coil devices 5a and 5b, the load interrupter switch 7 subsequently being able to interrupt the already limited current completely.

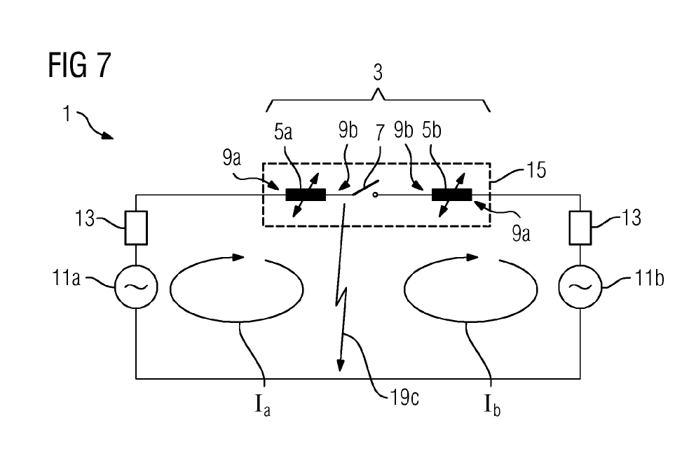

Finally, FIG. 7 shows the same electrical supply system 1 as in FIG. 6, but with a short circuit at an alternative short-circuit position 19c, that is to say, in this case too, again to a line region that is arranged between a coil device 5a and the load interrupter switch. A short circuit of this kind in turn results in multiple partial currents, for which, again, the short-circuit current path suppled by the first current source 11a is denoted by Iₐ and the path supplied by the second current source 11b is denoted by I_{b}. For the two short-circuit current paths Iₐ and I_{b}, limiting to the prescribed limit current by the respective coil device 5a or 5b situated in the current path initially takes place. For the second current path I_{b}, this limit current can be effectively interrupted by the load interrupter switch 7 in a subsequent step, since the load interrupter switch 7 is designed to interrupt the already limited current, of course.

As shown in the various examples, it is thus possible, in the case of the electrical supply systems of FIGS. 3 and 4 and also 6 and 7, for the resulting short-circuit currents always to be reliably limited inside the current limiter devices 3 by at least one of the current-limiting coil devices 5, 5a or 5b even for short-circuit positions 19c, and, for the more favorable short-circuit positions 19b, even to be interrupted completely by the load interrupter switch 7 in a subsequent step, without said load interrupter switch necessarily needing to be designed to interrupt the full short-circuit current not yet limited by coil devices. If a short circuit at the positions 19c cannot be ruled out with sufficient certainty, it is therefore expedient for the load interrupter switch 7 to be arranged on a load side 9b of the respective coil device 5, 5a, 5b, which is remote from the current source side 9a.

For the example of FIG. 7 too, it may be useful to use two further load interrupter switches, not shown here, on the two sides 9a between the actual current limiter device 3 and the current sources 11a and 11b to control the short circuit at the position 19c or a corresponding position next to the second coil device 5b. In this case, in the butterfly arrangement shown in FIG. 7 too, it is possible to interrupt the short-circuit current for all short-circuit types quickly for the respective coil devices 5a and 5b.

What is claimed is:

1. A current limiter device for limiting a short-circuit current in a superordinate electrical supply system, the device comprising:
a current-limiting coil device; and
a switch connected in series with the coil device;
wherein the switch comprises a load interrupter switch.

2. The current limiter device as claimed in claim 1, wherein the load interrupter switch is electrically connected to a first connection side of the coil device;
the first connection side comprising one of two connection sides in the superordinate electrical supply system with a higher-impedance connection to a current source of the electrical supply system in the event of limiting.

3. The current limiter device as claimed in claim 1, wherein the load interrupter switch is adjacent to the coil device.

4. The current limiter device as claimed in claim 1, wherein there is no circuit breaker connected in series with the coil device.

5. The current limiter device as claimed in claim 1, wherein the load interrupter switch has a switching capacity corresponding to at least a current limited by the coil device and lower than an unlimited short-circuit current.

6. The current limiter device as claimed in claim 1, wherein which the load interrupter switch has a switching capacity corresponding to no more than five times a prescribed rated current of the superordinate electrical supply system.

7. The current limiter device as claimed in claim 1, wherein the load interrupter switch has a switching capacity of no more than 10 kA at a rated voltage of 66 kV or less.

8. The current limiter device as claimed in claim 1, wherein the load interrupter switch has an opening time of no more than 30 ms.

9. The current limiter device as claimed in claim 1, wherein the current-limiting coil device includes at least one coil comprising a superconductive conductor material.

10. The current limiter device as claimed in claim 1, further comprising a cryostat;
wherein at least a part of the current-limiting coil device and a connection of the load interrupter switch are arranged inside the cryostat.

11. The current limiter device as claimed in claim 1, further comprising at least two current-limiting coil devices; and
wherein the load interrupter switch is arranged between the at least two coil devices.

12. The current limiter device as claimed in claim 1, further comprising a normally conductive parallel impedance electrically connected in parallel with the current-limiting coil device and the load interrupter switch.

13. The current limiter device as claimed in claim 1, wherein the current-limiting coil device comprises a resistively current-limiting coil device.

14. The current limiter device as claimed in claim 1, wherein the current-limiting coil device comprises an inductively/resistively current-limiting coil device.

15. A method for limiting a short-circuit current in an electrical supply system with a current limiter device, the method comprising:
in the event of a short circuit, limiting
a short-circuit current flowing through a current-limiting coil device to a prescribed limit current by means of the coil device; and
interrupting the limit current flowing through a load interrupter switch by opening the load interrupter switch.
